(19) United States
(12) Patent Application Publication
(10) Pub. No.: US 2009/0267846 A1
(43) Pub. Date: Oct. 29, 2009

(54) Electromagnetic Field Power Density Monitoring System and Methods

(76) Inventors: Michael P. Johnson, Poway, CA (US); Charles G. Thurston, Solana Beach, CA (US)

Correspondence Address: TAROLLI, SUNDHEIM, COVELL & TUMMINO L.L.P., 1300 EAST NINTH STREET, SUITE 1700, CLEVEVLAND, OH, 44114, US

(21) Appl. No.: 12/110,783

(22) Filed: Apr. 28, 2008

(51) Int. Cl. G01R 29/08; G08B 23/00

(52) U.S. Cl. 343/703; 340/573.1

(57) ABSTRACT

Systems and methods for monitoring electromagnetic field power density are disclosed. The system includes a broadband antenna configured to convert a plurality of electromagnetic waves at a plurality of frequencies into a broadband signal. The system also includes a power adjustment system configured to passively selectively attenuate the broadband signal to provide a filtered output signal for a predetermined range of frequencies. The system further includes an output system configured provide an indicator to an end-user of the system if the filtered output signal exceeds a predetermined threshold level that characterizes a predetermined electromagnetic power density threshold.

### TECHNICAL FIELD

The present invention relates generally to electromagnetic field power density monitoring system and methods, and more particularly to passive electromagnetic field power density monitoring system and methods.

### BACKGROUND

Body tissues that are subjected to very high levels of radio frequency (RF) energy may suffer serious heat damage. These effects depend on the frequency of the energy, the power density of an RF field that strikes the body and factors such as the polarization of the wave. At frequencies near the body's natural resonant frequency, RF energy is absorbed more efficiently, and an increase in heating occurs. Moreover, individual body parts may be resonant at different frequencies. As an example, an adult head is resonant around 400 megahertz. As the frequency is moved farther from resonance, less RF heating generally occurs. Specific absorption rate (SAR) is a term that describes the rate at which RF energy is absorbed in tissue.

Maximum permissible exposure (MPE) limits are based on whole-body SAR values, with additional safety factors included as part of the standards and regulations. Thus, safe exposure limits vary with frequency. The MPE limits define the maximum electric and magnetic field strengths or the plane-wave equivalent power densities associated with these fields that a person may be exposed to without harmful effect and with an acceptable safety factor.

Additionally, in some environments of application, such as battlefields and battle training grounds, excessive RF energy can cause accidental actuation of electro-explosive devices or other electrically activating devices. Such an unintended actuation could have safety (e.g., premature firing) or reliability (e.g., duding) consequences that can be referred to as hazards of electromagnetic radiation to ordnance (HERO).

### SUMMARY

One aspect of the present invention is related to a system for monitoring electromagnetic field power density. The system includes a broadband antenna configured to convert a plurality of electromagnetic waves at a plurality of frequencies into a broadband signal. The system also includes a power adjustment system configured to passively selectively attenuate the broadband signal to provide a filtered output signal for a predetermined range of frequencies. The system further includes an output system configured to provide an indicator to an end-user of the system if the filtered output signal exceeds a predetermined threshold level that characterizes a predetermined electromagnetic power density threshold.

Another aspect of the invention is related to a passive circuit for monitoring electromagnetic field power density. The circuit comprises a broadband antenna configured to convert a plurality of electromagnetic waves at a plurality of different frequencies into a broadband signal. The circuit also comprises a power adjustment system comprising a plurality of passive bandpass filters, each of the plurality of the bandpass filters configured to passively selectively attenuate the broadband signal at a predetermined band of frequencies and provide a filtered output signal. The circuit further comprises an output system configured to passively output one of a visual, audio and tactile indicator to an end user of the circuit when the filtered output signal exceeds a predetermined threshold level that corresponds to a predetermined electromagnetic power density threshold.

Yet another aspect of the invention is related to a method for monitoring an electromagnetic field power density. A broadband signal is received. The broadband signal is passively selectively attenuated, and a filtered broadband signal is provided. An indicator is activated if the filtered broadband signal exceeds a predetermined threshold level that corresponds to a predetermined electromagnetic power density threshold.

### BRIEF DESCRIPTION OF THE DRAWINGS

FIG. 1 illustrates a block diagram of a system for monitoring electromagnetic field power density in accordance with an aspect of the invention.

FIG. 2 illustrates another block diagram of a system for monitoring electromagnetic field power density in accordance with an aspect of the invention.

FIG. 3 illustrates an example of a circuit for a system for monitoring electromagnetic field power density in accordance with an aspect of the invention.

FIG. 4 illustrates an example of a broadband antenna in accordance with an aspect of the invention.

FIG. 5 illustrates another view of the antenna illustrated in FIG. 4 in accordance with an aspect of the invention.

FIG. 6 illustrates a graph depicting power density plotted as a function of frequency in accordance with an aspect of the invention.

FIG. 7 illustrates another example of a system for monitoring electromagnetic field power density in accordance with an aspect of the invention.

FIG. 8 illustrates an example of a garment with a system for monitoring electromagnetic field power density mounted in accordance with an aspect of the invention.

FIG. 9 illustrates a flow chart of a methodology for monitoring electromagnetic field power density in accordance with an aspect of the invention.

### DETAILED DESCRIPTION

Systems and methods are disclosed that employ a broadband antenna to receive electromagnetic waves over a broad range of frequencies and provide a broadband signal corresponding to the electromagnetic waves absorbed by the broadband antenna. The broadband signal can be provided to a power adjustment system. The power adjustment system can selectively attenuate the broadband signal at a predetermined range of frequencies and provide a filtered broadband signal to an output system. The output system can activate an indicator that notifies an end user of an electromagnetic field power density status. A circuit implementing the system can be a passive circuit, such that no external power source (e.g., batteries) are required to operate the circuit.

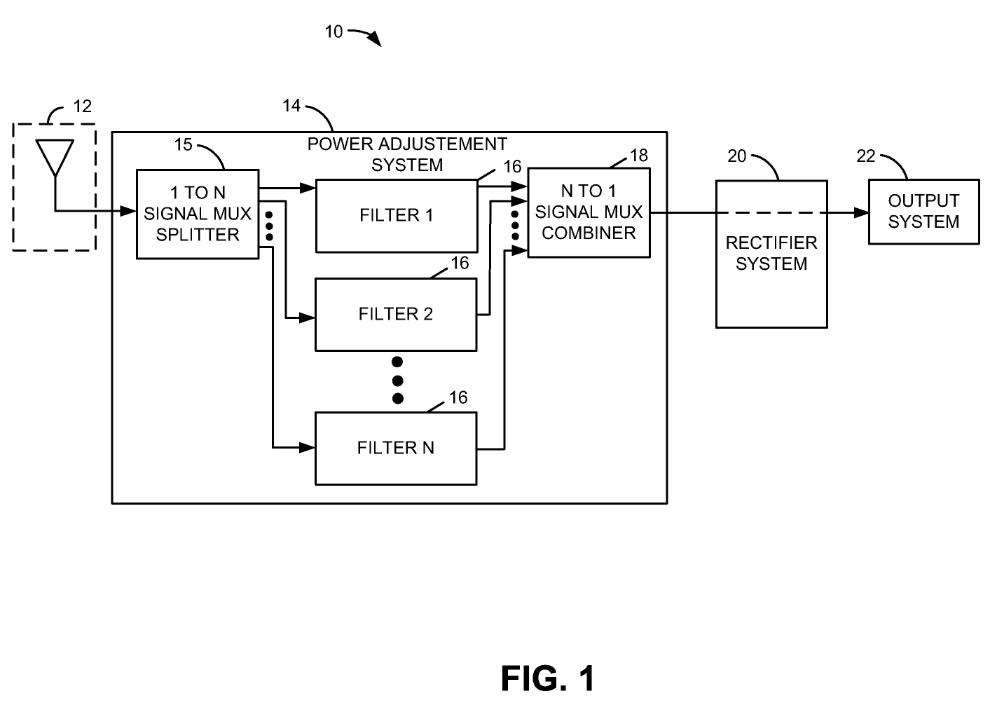

FIG. 1 illustrates a system 10 for monitoring electromagnetic field power density in accordance with an aspect of the invention. Electromagnetic field power density is the amount of electromagnetic power distributed over a given unit area perpendicular to the direction of travel. Electromagnetic field power density is typically measured in Watts per meter squared (W/m²). The system 10 can be implemented, for example, as a passive system (e.g., requiring no external power for operation). The system 10 includes a broadband antenna 12 that can receive electromagnetic waves in a broad range of frequencies, such as radio frequencies (RF) waves at a frequency of over 3 octaves or more. The broadband antenna 12 can be configured such that a broadband spectrum of incident propagating electromagnetic energy induces a broadband potential energy in an electric circuit; the potential energy is hereinafter referred to as a “broadband signal.” The broadband signal can be provided to a power adjustment system 14.

The power adjustment system 14 can include a 1-to-N signal multiplex splitter 15, wherein N is an integer greater than 1. The 1-to-N signal multiplex splitter 15 can provide the broadband signal to N bandpass filters 16. Each of the N bandpass filters 16 can receive the broadband signal and selectively attenuate signals that are within the corresponding passband of a given bandpass filter 16, while blocking signals outside the corresponding passband. The bandpass filters 16 can be implemented, for example, with passive circuit components (e.g., resistors, capacitors and inductors). Outputs of the bandpass filters 16 can be provided, for example, to an N-to-1 signal multiplex combiner 18 that combines the outputs of the bandpass filters 16 together. The N-to-1 signal multiplex combiner 18 can output a filtered output signal to a rectifier system 20.

As is known, the percentage of electromagnetic energy converted into energy in an electric circuit (e.g., current and voltage) can change as a function of frequency. That is, for certain frequency bands, more or less energy from propagating electromagnetic waves is converted to electrical energy by an antenna (e.g., the broadband antenna 12) than for electromagnetic waves in other frequency bands. Thus, the bandpass filters 16 can include a compensating resistance that selectively adjusts the amount of current in the different bands of operation. Additionally, the compensating resistance of the bandpass filters 16 can also be selected based on a predetermined threshold of electromagnetic power density associated with the frequency of the given bandpass filter 16, wherein the predetermined threshold is dependent on the particular environment of application for the system 10.

The rectifier system 20 can convert the filtered output signal from an alternating current (AC) signal to a direct current (DC) signal, which DC signal can be provided to an output system 22. The output system 22 can, for example, provide an indicator to an end user of the system 10 when the rectified filtered output signal exceeds a predetermined threshold level. The end user of the system 10 could be, for example, a person in relatively close physical proximity with the system 10.

In one example, the predetermined threshold level can correspond to a maximum electromagnetic field power density of electromagnetic energy to which the end-user of the system 10 can be safely exposed, which is commonly referred to as a maximum permissible exposure (MPE). Moreover, as is known, the MPE for electromagnetic field power density changes as a function of frequency. For example, an end user can be safely exposed to a higher density of electromagnetic fields at 500 MHz than one can at 400 MHz. As an alternative, the predetermined threshold could correspond to a maximum safe power density to which nearby electro-explosive devices or otherwise electronically actuatable device can be exposed. In yet another alternative, the system 10 could be implemented on or near a broadband transmitting antenna to give an indication that the broadband antenna is transmitting at a predetermined power density (corresponding to the predetermined threshold). One skilled in the art will appreciate that the system 10 could be implemented in other application environments as well.

The indicator could be implemented, for example, as a visual indicator (e.g., a light emitting diode (LED), a liquid crystal display (LCD)), an audio indicator (e.g., a loudspeaker) or a tactile indicator (e.g., a vibrating system). One skilled in the art will appreciate that other indicators could be employed as well. The predetermined threshold, the indicator's power efficiency and the antenna gain dictate the bands over which the system 10 can be used passively for a given indicator type. For relatively high power indicators, (e.g., a vibrating system), external power (e.g., a battery) could be employed. The output system 22 can be configured, for example to provide an oscillating signal to the indicator causing the indicator to activate periodically. For instance, if the indicator is implemented as an LED, the LED can blink in response to receiving the oscillating signal. In the present example, since the broadband signals are combined (via the N-to-1 multiplex combiner 18), the indicator is activated if the total electromagnetic power density (across the broadband range of frequencies) exceeds the predetermined threshold.

The system 10 could be implemented, for example, to notify the end-user of the system 10 of the status of electromagnetic field power density exposure. In particular, in one example, the system 10 can notify the end-user that he/she is being exposed to an unsafe electromagnetic filed power density level. In such an implementation, the system 10 could be interwoven on to a garment (e.g., a uniform, an item of clothing, etc.). As another alternative, the system 10 could be mounted and encased as a separate unit that could, for instance be attached (e.g., via a belt clip, touch fasters such as hook-and-loop fasters, etc.) to a garment.

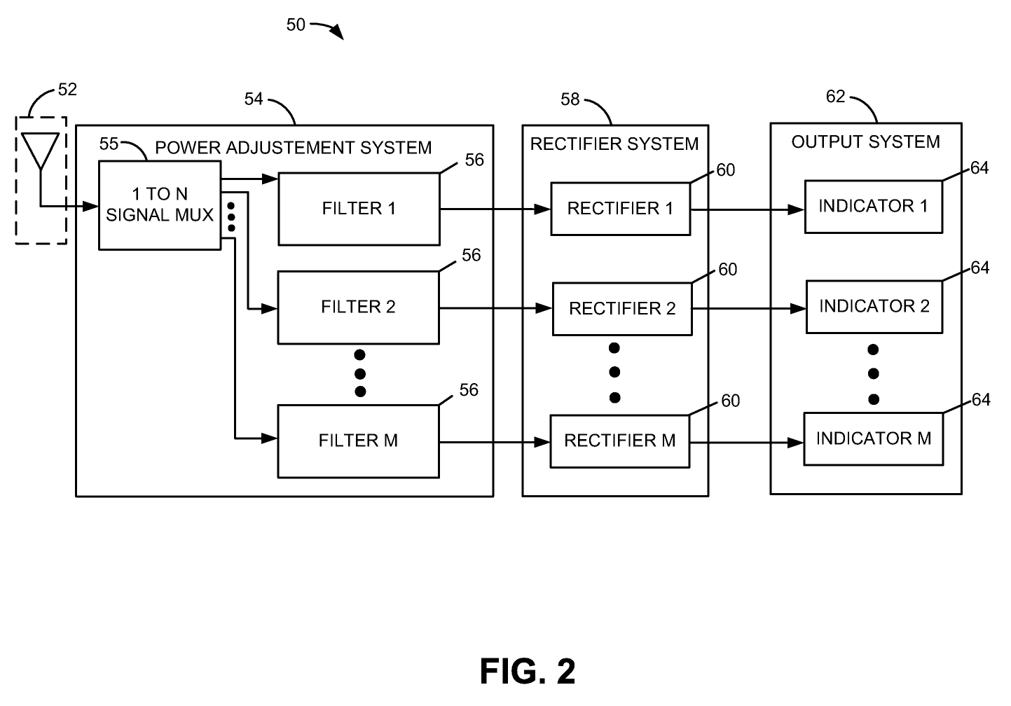

FIG. 2 illustrates another example of a system 50 for monitoring electromagnetic field power density in accordance with an aspect of the invention. The system 50 can be implemented, for example, as a passive system (e.g., requiring no external power for operation). The system 50 includes a broadband antenna 52 that can receive electromagnetic waves in a broad range of frequencies, such as radio frequencies (RF) over at least 3 octaves. The broadband antenna 52 be configured to provide a broadband signal that can be provided to a power adjustment system 54 at a 1-to-M multiplex splitter 55, wherein M is an integer greater than one. The 1-to-M multiplex splitter 55 can provide the broadband signal to M bandpass filters 56 of the power adjustment system 54.

Each of the M bandpass filters 56 can receive the broadband signal and selectively attenuate signals that are within the corresponding passband of a given bandpass filter 56, while blocking signals outside the corresponding passband. The bandpass filters 56 can be implemented, for example, with passive circuit components (e.g., resistors, capacitors and inductors). Outputs of the bandpass filters 56 can be provided a rectifier system 58.

As is known, the percentage of electromagnetic energy converted into electrical energy (e.g., current and voltage) changes as a function of frequency. Thus, the bandpass filters 56 can include a compensating resistance that adjusts the amount of current selectively attenuated by the bandpass filters 56. Additionally, the compensating resistance of the bandpass filters 56 can also be selected based on a predetermined threshold of electromagnetic power density associated with the frequency of the given bandpass filter 56.

The rectifier system 58 include M number of rectifiers 60 that can each convert a corresponding filtered output signal of a corresponding bandpass filter 56 from an AC signal to a DC signal and pass the corresponding DC signal to an output system 62. The output system 62 can, for example, include M number of indicators 64 (each corresponding to a rectifier 60 and a bandpass filter 56) that provide an indication to an end user of the system 50 when a rectified filtered output signal from the corresponding bandpass filter 56 exceeds a predetermined threshold level at a range of frequencies within the passband of the corresponding bandpass filter 56. The end user of the system 50 could be, for example, a person in relatively close physical proximity with the system 50.

The predetermined threshold level can correspond to MPE for the end user of the system 50. Moreover, as is known, the MPE for electromagnetic field power density changes as a function of frequency. For example, an end user can be safely exposed to a higher density of electromagnetic fields at 500 MHz than one can at 400 MHz. As an alternative, the predetermined threshold could correspond to a maximum safe power density to which nearby electro-explosive devices or otherwise electronically actuatable device can be exposed. In yet another alternative, the system 50 could be implemented on or near a broadband transmitting antenna to give an indication that the broadband antenna is transmitting at a predetermined power density (corresponding to the predetermined threshold) at one or more bands of frequencies. One skilled in the art will appreciate that the system 50 could be implemented in other application environments as well.

The indicators 64 could be implemented, for example, as visual indicators (e.g., LED, LCD, etc.), audio indicators (e.g., loudspeakers) or a tactile indicators (e.g., a vibrating system). One skilled in the art will appreciate that other indicators could be employed as well. The output system 62 can be configured, for example to provide an oscillating signal to a given indicator 64 causing the given indicator 64 to activate periodically. For instance, if the given indicator 64 is implemented as an LED, the LED can blink in response to receiving the oscillating signal.

The system 50 could be implemented, for example, to notify the end-user of the system 50 of the status of electromagnetic field power density exposure, for frequencies bands associated with the indicators 64. The system 50 could be interwoven on to a garment (e.g., a uniform, an item of clothing, etc.). Alternatively, the system 50 could be mounted and encased as a separate unit that could, for instance be attached (e.g., via a belt clip, hook-and-loop fasters, etc.) to a garment. In another alternative, the system 50 could be attached to another system that transmits electromagnetic waves (e.g., a communication device).

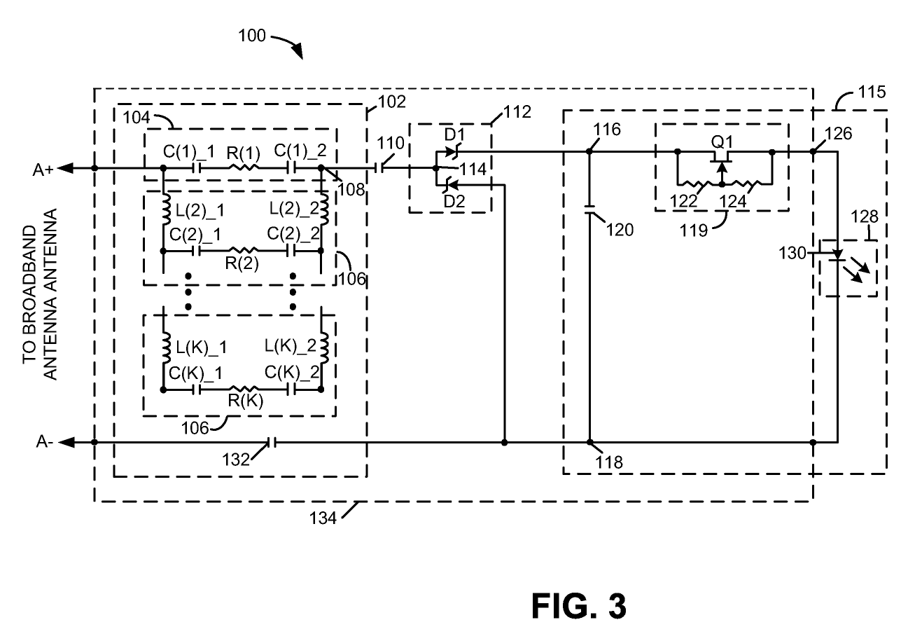

FIG. 3 illustrates an example of a circuit 100 for a system (e.g., the system 10 illustrated in FIG. 1) in accordance with an aspect of the invention. Moreover, although the circuit 100 is directed to the system 10 illustrated in FIG. 1, one skilled in the art could adapt the circuit 100 to the system 50 illustrated in FIG. 2. The circuit 100 could be employed, for example, to monitor an electromagnetic field power density. The circuit 100 includes a power adjustment system 102 that receives a broadband signal from a positive terminal of a broadband antenna indicated as node A+.

The power adjustment system 102 can be implemented, for example, as a ladder filter with K rungs 104 and 106, where K is an integer greater than one. The first rung 104 of the ladder can include, for example, a multiplexed splitting capacitor C(1)_1, a resistor R(1) and a multiplexed combining capacitor C(1)_2. The capacitance of C(1)_1 and C(1)_2 can be selected, for example, with a relatively low capacitance that passes the highest frequency signals that are received by the power adjustment system 102 to the resistor R(1). As discussed herein, as the frequency of a signal received by the broadband antenna changes, so does the amount of energy converted into electrical energy. Thus, R(1) can be selected to have a relatively high resistance to reduce the current through the power adjustment system 102. R(1) can be coupled to an output node 108 of the power adjustment system 102.

Rungs 2 to K of the ladder filter can be implemented with a pair of inductors L(X)_1 and L(X)_2, (wherein X is the given rung number between 2 and K) coupled to the previous rung (e.g., rung X−1). The first inductor L(X)_1 can also be coupled to a multiplexed splitting capacitor C(X)_1. C(X)_1 can also be coupled to a resistor R(X). R(X) can be coupled to a multiplexed combining capacitor C(X)_2, that can be coupled to L(X)_2, thereby forming a circuit path between L(X)_1, C(X)_1, R(X), C(X)_2 and L(X)_2.

In the present example, L(X)_1 and L(X)_2 can have about equal inductances, while C(X)_1 and C(X)_2 can have about equal capacitances. The power adjustment system 102 can be designed such that L(X)_1 and L(X)_2 can have an inductance lower than L(X+1)_1 and L(X+1)_2, such that each set of inductors L(X)_1 and L(X)_2 passes frequencies higher than the proceeding rungs (and passes frequencies lower than preceding rungs). Moreover, C(X)_1 and C(X)_2 can have a capacitance greater than C(X−1)_1 and C(X−1)_2, respectively, such that each pair of capacitors C(X)_1 and C(X)_2 passes a frequencies lower than the preceding rungs (and passes frequencies higher than proceeding rungs). Additionally, R(X) can be selected to attenuate the received signal at the associated frequency. The amount of attenuation can change as a function of frequency. As an example, in one implementation, the resistance of R(X) can be based on both the amount of RF energy absorbed by the associated broadband antenna, as well as a predetermined electromagnetic power density threshold associated with the frequencies passed by the rung. Accordingly, for each path between L(X)_1, C(X)_1, C(X)_2, R(X) and L(X)_2 for a given rung 106 allows a lower frequency with a higher current to pass through the given rung 106 than a preceding rung (e.g., rung X−1).

The number of rungs can be chosen, for example, based on the accuracy required in the particular application environment. Typically, the more accuracy required, (e.g., the tigher the difference between the minimum and maximum frequency thresholds for each rung), the more rungs required. One skilled in the art will appreciate the levels of accuracy needed in the particular application environment that the circuit 100 is to be employed. As one example, the last rung (rung K) can be designed to pass frequencies between about 250 MHz and about 350 MHz. It is to be understood that other configurations for the power adjustment system 102 are possible as well. One skilled in the art will understand and appreciate the variety of ways that the power adjustment system 102 can be implemented.

The output node 108 of the power adjustment system 102 can be coupled to a first coupling capacitor 110. The first coupling capacitor 110 can also be coupled to a rectifier 112 at a node indicated at 114. The rectifier 112 can include, for example, a pair of Zener diodes, D1 and D2. A positive terminal of D1 can be coupled to the node 114, while a negative terminal of D2 can be coupled to the node 114. A negative terminal of D1 can be coupled to an input node of an output system 115, indicated at 116, while a positive terminal of D2 can be coupled to a node indicated at 118.

A second coupling capacitor 120 can also be coupled to node 116. The second coupling capacitor 120 can also be coupled to node 118. Node 116 can also be coupled to an input terminal of an integrate and dump component 119. The integrate and dump component 119 can include, for example, a field effect transistor (FET) Q1 such as a Junction Field Effect Transistor (JFET) coupled to node 116 at a drain terminal. A resistor 122 can be coupled between the drain terminal and a gate terminal of Q1. Another resistor 124 can be coupled between the gate terminal of Q1 an a source terminal of Q1 at a node indicated at 126. It is to be understood that other configurations are possible as well. For example, Q1 can be implemented as a symmetric JFET, such that the drain and source terminals could be reversed. Additionally, a different FET, such as a metal-oxide semiconductor field effect transistor (MOSFET) could be employed in place of Q1.

An input terminal of an indicator 128 can be coupled to node 126. In the present example, the indicator 128 is implemented as an LED 130, but one skilled in the art will appreciate that the indicator 128 could also be implemented as an auditory indicator or a tactile indicator. An output terminal of the indicator 128 can be coupled to node 118. A third coupling capacitor 132 of the power adjustment system 102 can be connected between the node 118 of the output system 115 and the negative terminal of the broadband antenna indicated at A−. It is to be understood that in some implementations, the negative terminal of the antenna A− could be implemented, for example, as an electrically neutral node (e.g., ground node).

Broadband signals are received by the broadband antenna and passed to the power adjustment system 102 through node A+. The power adjustment system 102 selectively attenuates the broadband signal at the filter rungs 104 and 106 and provides a filtered output signal to the first coupling capacitor 110. If the filtered output signal is above a cutoff frequency of the first coupling capacitor 110, the filtered output signal will be passed to the rectifier 112. The rectifier 112 cuts off portions of the filtered output signal that are below a threshold voltage (e.g., about 0.7 volts (V)) and passes a rectified filtered output signal to the output system 115. The rectified filtered output signal is integrated by the integrate and dump component 119. When the signal charge at node 126 exceeds a threshold voltage of the indicator, the indicator 128 (e.g., the LED 130) is activated (e.g., turned on) for a brief time, as the charge at node 126 dissipates. After dissipating, the indicator 128 is deactivated until the charge at node 126 is restored by a subsequent integration of the rectified filtered output signal. The dissipation time can be dependent, for example, on the capacitance of the second coupling capacitor 120.

The charging and dissipating can produce an oscillating indicator 128 (e.g., the indicator 128 is turned off and on). The output of the output system 115 (e.g., node 118) can be fed back into the input via D2 to stabilize the circuit 100. Additionally, the output of the output system 115 (e.g., node 118) can be coupled to the third coupling capacitor 132 at the power adjustment system 102. The third coupling capacitor 132 can have a capacitance about equal to the first coupling capacitor 110.

In the present example, the power adjustment system 102, the rectifier 112 and at least a portion of the output system 115, namely, the second coupling capacitor 120 and the integrate and dump component 119, can be fabricated on an integrated circuit (IC) chip 134. Such an implementation can allow for a smaller overall physical size of the circuit 100. However, it is to be understood that in other implementations, discrete circuit components could be employed as well.

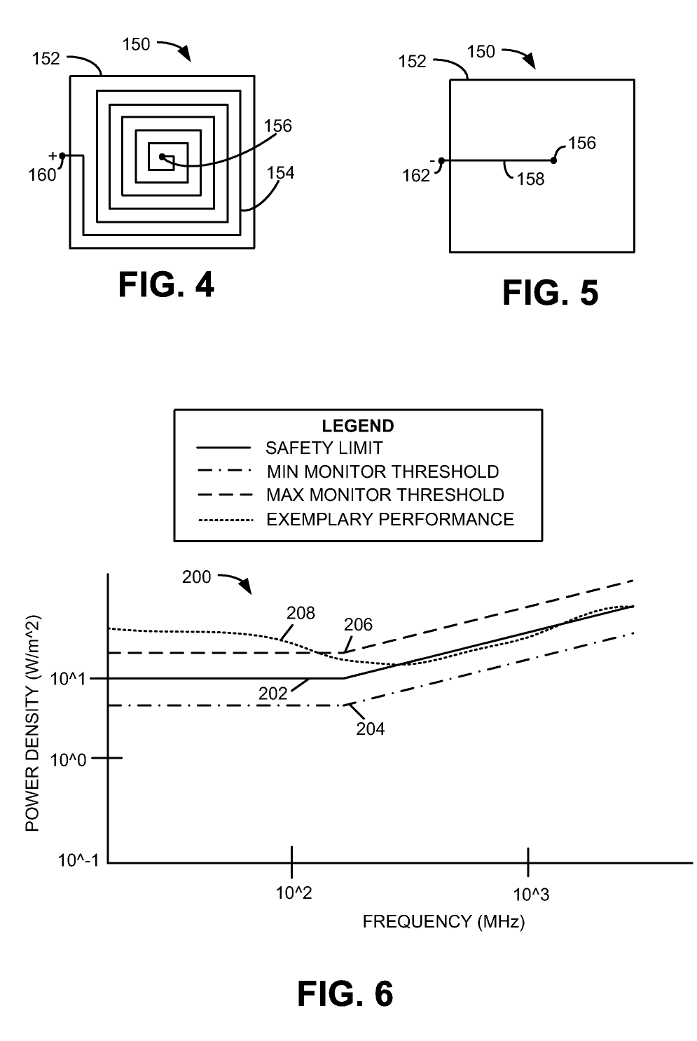

FIGS. 4 and 5 illustrate an example of a broadband antenna 150 that could be employed in accordance with an aspect of the invention. The broadband antenna 150 can include a printed circuit board (PCB) 152 with a spiral antenna 154 etched onto the PCB. FIG. 4 illustrates a front view of the broadband antenna 150, while FIG. 5 illustrates a back view of the broadband antenna 150. The spiral antenna 154 could be formed, for example, as a square Archimedean spiral. The spiral antenna 154 can also include a through hole 156 in the center of the spiral antenna 154 that can connect a backside of the PCB 152. A terminal feed line 158 can be coupled to the through hole 156.

A terminal on the front side of the PCB 152 indicated at 160 can be implemented as a positive terminal for the broadband antenna 150. Additionally, a second terminal indicated at 162 on the backside of the PCB 152 can be implemented as a negative terminal of the broadband antenna 150. The terminals 160 and 162 can be coupled, for example, to a circuit (e.g., the circuit 100 illustrated in FIG. 3) employed to monitor power density of electromagnetic energy.

FIG. 6 illustrates a power density graph 200 in accordance with an aspect of the invention. In FIG. 6, power density in W/m² is plotted as a function of frequency in MHz. A first line, indicated at 202 corresponds to an MPE of an electromagnetic field power density in a controlled environment. In the present example, a controlled environment can be considered to be an environment where most or all electromagnetic energy is being radiated from known sources, such as a battlefield. An uncontrolled environment can referred to an environment where most or all of the electromagnetic energy is being radiated from unknown sources (e.g., wireless phones), such as an urban area. As is known, the MPE of an electromagnetic field power density for a controlled environment is generally higher at a given frequency than the MPE of an electromagnetic field power density for an uncontrolled environment at that given frequency. Moreover, although in the present example the system is calibrated to be employed in a controlled environment, one skilled in the art will appreciate that the system could be calibrated to be employed in an uncontrolled environment as well. As is shown, from about 0 to about 300 MHz, the MPE of an electromagnetic field power density is about 10 W/m². At about 300 MHz, the MPE for electromagnetic field power density increases as a function of frequency.

Second and third lines 204 and 206 can indicate tolerance levels for a circuit made to monitor electromagnetic field power density (e.g., the circuit 100 illustrated in FIG. 3). The second line 204 can indicate a minimum power density for which an indicator is activated while still approving the circuit for use. The second line 204 can be, for example about 3 decibels (dB) lower than the actual MPE of an electromagnetic field power density. The third line 206 can indicate a maximum power density for which an indicator is not activated while still approving the circuit for use. The third line 206 can be, for example about 3 dB higher than the actual MPE of electromagnetic field power density.

A fourth line 208 can correspond to an example of a simulated result of a circuit (e.g., the circuit 100 illustrated in FIG. 3) that falls within the threshold tolerances for frequencies above about 200 MHz. The fourth line 208 indicates a tested threshold level of power density required to activate an indicator. As is shown, the simulation results fall within the tolerance lines 204 and 206 above about 200 MHz. Accordingly, a circuit conforming to the test results indicated by the fourth line 208 could be approved for use above about 200 MHz.

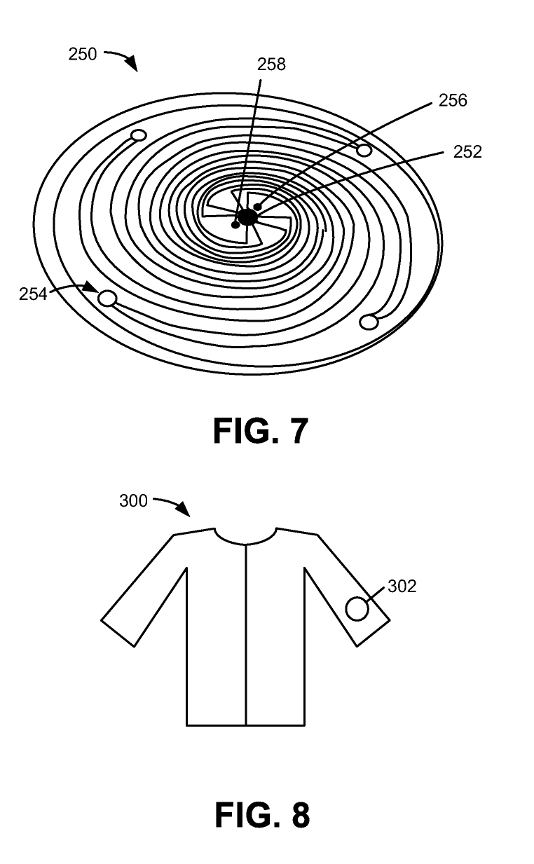

FIG. 7 illustrates an example of a system 250 for monitoring electromagnetic field power density in accordance with an aspect of the invention. The system 250 can be interwoven into a textile (e.g., fabric) of a garment, such as a uniform. The system 250 can include a circuit (such as the circuit 100 illustrated in FIG. 3) that can monitor electromagnetic field power density. An IC chip of the circuit (e.g., the IC chip 134 illustrated in FIG. 3) could be mounted, for example on a reverse side of the system 250 (not shown). An indicator 252 (e.g., the LED 130 illustrated in FIG. 3) coupled to the IC chip can be mounted on a front side of the system 250.

The system 250 can also include a broadband antenna 254 coupled to the IC chip at terminals 256 and 258. The broadband antenna 254 could be implemented as a symmetric antenna such that either terminals 256 and 258 could be the positive or negative terminals of the broadband antenna 254. Moreover, the broadband antenna 254 can have, for example, a substantially spiral shape, although one skilled in the art will appreciate that other shapes could be employed as well.

The system 250 can be coated with a waterproof shield (e.g., plastic) such that the electromagnetic field power density monitor can be interwoven into a textile of a garment and washed. The system 250 could be configured such that when the system 250 is exposed to an electromagnetic field power density greater than the MPE for a given frequency, the indicator 252 is activated (e.g., flashes). The activated indicator 252 thus warns an end user of the system that he/she is being exposed to an electromagnetic field with a power density that is greater than a safe amount, allowing the end user to take appropriate action.

FIG. 8 illustrates an example of a garment 300 (e.g., a uniform) with a system for monitoring electromagnetic field power density (e.g., the system 250 illustrated in FIG. 7) mounted (e.g., interwoven) into the textile of the garment. In the present example, the system 302 is located on a sleeve of the garment 300, although one skilled in the art will appreciate that the system 302 could be mounted elsewhere, such as the chest or shoulder portion of the garment 300.

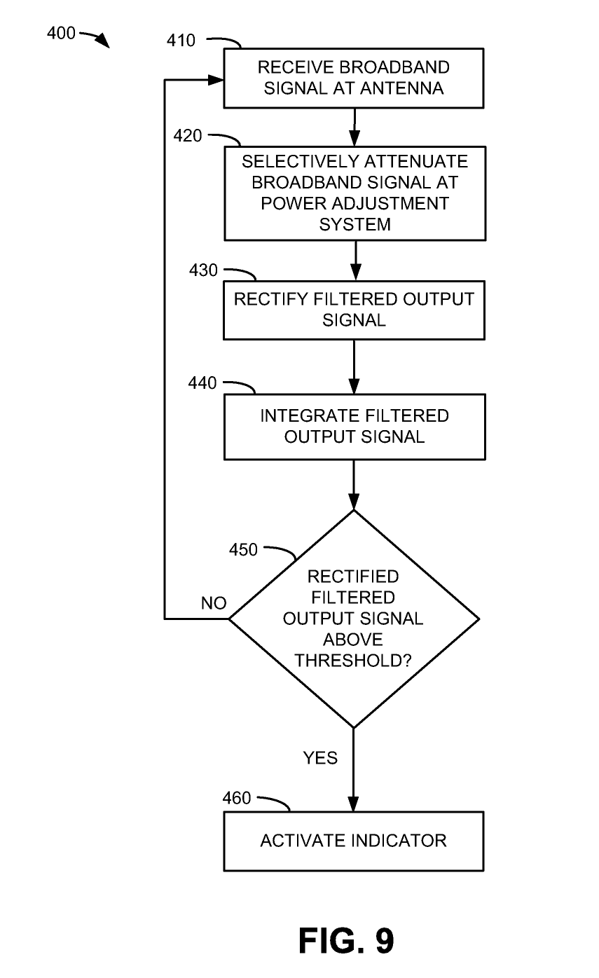

In view of the foregoing structural and functional features described above, methodologies will be better appreciated with reference to FIG. 9. It is to be understood and appreciated that the illustrated actions, in other embodiments, may occur in different orders and/or concurrently with other actions. Moreover, not all illustrated features may be required to implement a method.

FIG. 9 illustrates a flow chart of a methodology 400 for monitoring electromagnetic density in accordance with an aspect of the invention. At 410, a broadband signal is received at a broadband antenna. At 420, the broadband signal is selectively attenuated by a power adjustment system. The power adjustment system could be implemented, for example, as a plurality of passive filters that selectively attenuate a current of the broadband signal at particular frequencies or ranges of frequencies. At 430 a rectifier receives and rectifies a filtered output signal of the power adjustment system. The rectified filtered output signal can be provided, for example to an output system. At 440, an integrate and dump component of the output system integrates the rectified filtered output signal to provide a signal that oscillates to an indicator (e.g., an LED).

At 450, a determination is made as to whether the rectified filtered output signal exceeds a threshold level. If the determination is negative (e.g., NO), the methodology 400 returns to 410. If the determination is positive (e.g., YES) the methodology 400 proceeds to 460. At 460 the indicator is activated (e.g., illuminated) to notify an end user that he/she is being exposed to a power density level that is above a predetermined limit.

What have been described above are examples of the present invention. It is, of course, not possible to describe every conceivable combination of components or methodologies for purposes of describing the present invention, but one of ordinary skill in the art will recognize that many further combinations and permutations of the present invention are possible. Accordingly, the present invention is intended to embrace all such alterations, modifications and variations that fall within the scope of the appended claims.

What is claimed is:

1. A system for monitoring electromagnetic field power density, the system comprising:
a broadband antenna configured to convert a plurality of electromagnetic waves at a plurality of frequencies into a broadband signal;
a power adjustment system configured to passively selectively attenuate the broadband signal to provide a filtered output signal for a predetermined range of frequencies; and
an output system configured to provide an indicator to an end-user of the system if the filtered output signal exceeds a predetermined threshold level that characterizes a predetermined electromagnetic power density threshold.

2. The system of claim 1, wherein the power adjustment system further comprises a plurality of filters configured to selectively attenuate the broadband signal, each of the plurality of filters selectively attenuating the broadband signal at a predetermined range of frequencies.

3. The system of claim 1, further comprising a rectifier system configured to rectify the filtered output signal and to provide a rectified filtered output signal to the output system.

4. The system of claim 1, wherein the power adjustment system is configured to selectively attenuate the broadband signal over at least three octaves.

5. The system of claim 1, wherein the broadband antenna comprises a textile woven antenna.

6. The system of claim 1, wherein the broadband antenna comprises a spiral antenna.

7. The system of claim 1, wherein the predetermined level corresponds to a maximum permissible exposure (MPE) of a power density for an end user of the system.

8. The system of claim 7, wherein the MPE of a power density for the end user changes as a function of frequency.

9. The system of claim 1, the output system further comprises:
a light emitting diode (LED); and
an integrate and dump component configured to provide an oscillating signal to the LED when the filtered output signals exceeds the predetermined threshold level, causing the LED to flash.

10. The system of claim 1, wherein:
the filtered output signal comprises a plurality of filtered output the output signals, each of the output signals having a predetermined range of frequencies; and
the output system comprises a plurality of indicators, wherein each indicator is associated with at least one output signal of the plurality of output signals.

11. A garment that includes the system of claim 1 interwoven into a textile of the garment.

12. A passive circuit for monitoring electromagnetic field power density, the circuit comprising:
a broadband antenna configured to convert a plurality of electromagnetic waves at a plurality of different frequencies into a broadband signal;
a power adjustment system comprising a plurality of passive bandpass filters, each of the plurality of the bandpass filters configured to passively selectively attenuate the broadband signal at a predetermined band of frequencies and provide a filtered output signal;
an output system configured to passively output one of a visual, audio and tactile indicator to an end user of the circuit when the filtered output signal exceeds a predetermined threshold level that corresponds to a predetermined electromagnetic power density threshold.

13. The circuit of claim 12, wherein the output system comprises an integrate and dump component configured to provide an oscillating output signal when the filtered output signal exceeds the predetermined threshold level.

14. The circuit of claim 12, wherein the broadband antenna comprises a textile woven broadband antenna.

15. The circuit of claim 12, wherein the power adjustment system is configured to selectively attenuate the broadband signal at over at least three octaves.

16. The system of claim 12, wherein the predetermined level corresponds to a maximum permissible exposure (MPE) of an electromagnetic field power density for the end user.

17. The system of claim 16, wherein a given bandpass filter of the plurality of bandpass filters selectively attenuates a current of the broadband signal corresponding to the MPE of an electromagnetic field power density at a frequency within a passband of the given bandpass filter.

18. The circuit of claim 12, wherein:
the filtered output signal comprises a plurality of filtered output signals each having a predetermined frequency range; and
the output system comprises a plurality of indicators, wherein each indicator is associated with at least one of the plurality of filtered output signals.

19. A method for monitoring an electromagnetic field power density, the method comprising:
receiving a broadband signal;
passively selectively attenuating the broadband signal;
providing a filtered broadband signal;
activating an indicator if the filtered broadband signal exceeds a predetermined threshold level that corresponds to a predetermined electromagnetic power density threshold.

20. The method of claim 19, wherein the predetermined threshold level corresponds to a maximum permissive exposure (MPE) of an electromagnetic field power density for a person.

21. The method of claim 20, wherein the MPE of an electromagnetic power density for a person changes as a function of frequency.

22. The method of claim 19, wherein the broadband signal is received at a broadband antenna interwoven into a textile.
